(19) United States
(12) Patent Application Publication
(10) Pub. No.: US 2016/0169650 A1
(43) Pub. Date: Jun. 16, 2016

(54) MISSILE FUSE AND METHOD OF SUPPLYING ELECTRICAL ENERGY TO THE MISSILE FUSE

(71) Applicants: JUNGHANS MICROTEC GMBH, DUNNINGEN-SEEDORF (DE); DIEHL & EAGLE PICHER GMBH, ROETHENBACH (DE)

(72) Inventors: HARALD WICH, LAUF (DE); ROBERT HUETTNER, NEETZE (DE)

(21) Appl. No.: 14/578,729

(22) Filed: Dec. 22, 2014

(30) Foreign Application Priority Data
Dec. 21, 2013 (DE) 102013021848.9

(51) Int. Cl. F42C 11/00; H01L 35/28

(52) U.S. Cl. CPC F42C 11/008; H01L 35/28

(57) ABSTRACT

A fuse of a missile has a power supply system containing a power supply unit with at least one hot side, at least one cold side and at least one thermo generator disposed between the hot and cold sides. In order to achieve rapid and reliable electricity generation for electrical units of the fuse, it is proposed that the power supply unit contain a pyro unit on its at least one hot side for producing heat by a combustion process.

### CROSS-REFERENCE TO RELATED APPLICATION

This application claims the priority, under 35 U.S.C. §119, of German application DE 10 2013 021 848.9, filed Dec. 21, 2013; the prior application is herewith incorporated by reference in its entirety.

### BACKGROUND OF THE INVENTION

### Field of the Invention

The invention relates to a fuse of a missile with a power supply system that contains a power supply unit with at least one hot side, at least one cold side and at least one thermo generator disposed between the sides.

Fuses of large projectiles usually have electrical or electronic components for controlling various processes, e.g. a safety function, an ignition function, a measurement function, such as a distance measurement function and similar. For supplying the electrical elements with operating energy it is known to fit fuses with batteries that provide the necessary operating voltage. Such batteries must, however, be able to be stored over a very long period with absolute reliability, so that very high quality and expensive batteries must be used. Moreover, batteries contain a relatively low ratio of energy content to weight, so that they take up a large amount of space within the fuse.

In order to solve this problem it is known to fit a fuse with a power supply unit that uses a heat source of the projectile for generating electricity by a thermoelectric effect. Such a fuse is known from published, non-prosecuted German patent application DE 3100506 A1, corresponding to U.S. Pat. No. 4,421,029. Forward regions of the projectile, which heat up significantly in flight, are used as the heat surface. Alternatively, the rear region of the projectile heated by the launch or heat from a tracer element is used.

### SUMMARY OF THE INVENTION

It is an object of the present invention to specify a fuse of a missile whose electrical elements can be reliably supplied with electricity.

The object is achieved by a fuse of the above-mentioned type, with which according to the invention the power supply unit contains a pyro unit on its at least one hot side for generating heat by a combustion process.

The invention starts from the consideration that when using the heat of friction on the front of the missile it takes a while until sufficient heat is available to produce the operating voltage of the electrical element. Moreover, there is a risk that the heat arising from friction is not sufficient depending on the firing situation. With a pyro unit there is sufficient heat for satisfactorily generating electricity very rapidly after ignition. Moreover, pyro units generally contain a very high energy density, so that they can be manufactured very compactly and only need a small installation space in the fuse.

The missile can be a guided missile with a rocket engine and especially a seeker head or a projectile for firing from a barrel, such as a grenade, an artillery round or similar. The projectile can be a spin-free projectile or a projectile for spinning flight. Self-guiding projectiles with a seeker head and a guidance unit for controlling a flight of the projectile are also advantageous. The power supply system is used to supply electrical elements of the missile with operating energy. The term electrical elements also covers electronic elements. The electrical elements can be elements of a seeker head, a guidance unit and/or of a fuse, wherein advantageously all elements of such a unit are supplied with operating energy from the power supply system.

The power supply unit is a unit for generating electrical energy from a temperature difference. For this purpose it can comprise one or more thermo generators, each with one or more generator elements. The generator element can e.g. be a Peltier element. A Peltier element contains at least one p-doped and one n-doped, especially square, semiconducting element, wherein the differently doped semiconducting elements are alternately connected above and below by electrically conducting connectors, so that e.g. current flows first through the p-doped and then through the n-doped semiconducting element and so on. A thermo generator generates voltage and current in combination with a load or circuit if there is a temperature difference between the hot side and the cold side. The power supply unit can contain a plurality of hot sides and cold sides, depending on the number of thermo generators present. Here each thermo generator advantageously contains a hot side and a cold side of the power supply unit. If there is a plurality of thermo generators, the same can be electrically connected in series or in parallel. Either together or each on their own, they generate the operating voltage and the operating energy that at least one electrical element of the missile requires for its operation.

The pyro unit is a unit that generates heat by combustion. It is a part of the power supply unit and is advantageously enclosed by a housing of the fuse, especially of the power supply unit, especially on all sides. The pyro unit is predominantly used advantageously, especially exclusively, for generating electricity. It contains a burner element, with e.g. a solid fuel, which releases heat during the combustion process. The pyro unit is implemented such that at least 10%, especially most, of the heat generated in the combustion process is fed to the thermo generator(s) of the power supply unit when operating the fuse.

In one advantageous embodiment of the invention, the power supply unit contains two thermo generators and the pyro unit is disposed between the thermo generators. The thermal energy can be taken off on both sides of the pyro unit for thermoelectric use, so that a good energy yield can be achieved. Advantageously, the thermo generators are disposed symmetrically with respect to each other, wherein the pyro unit can form a plane of symmetry of the two thermo generators relative to each other. By a mirror image disposition on both sides of the pyro unit, a uniform thermal load on the thermo generators can be achieved. The cold sides of the two thermo generators can be turned in opposite directions and each can advantageously be disposed remotely from the pyro unit. In order to achieve a uniform mechanical loading of the thermo generators, the symmetry is oriented perpendicular to the axial direction of the fuse or missile.

Another advantageous embodiment of the invention provides that the pyro unit contains a burner element that is implemented at least essentially as a planar plate. This enables good heat distribution in the power supply unit to be achieved. The plate is advantageously a circular disc with its central point on the axis of the missile. The burner element can consist of a solid fuel.

During the combustion process the heat required for generating electricity exists within a very short time. Following the combustion process the pyro unit cools back down, so that the heat is only available for a while. In order to be able to generate electricity for as long as possible, it is advantageous if a heat reservoir is disposed between the at least one thermo generator of the power supply unit and the pyro unit. Heat of combustion can be fed to the heat reservoir, the heat being stored in the heat reservoir and then output again. Depending on the nature of the heat reservoir, a fast or slow heat output can be set, so that the heat output can be adapted to the desired electricity generation time period. The heat reservoir is advantageously a solid state reservoir, which even remains solid in the maximally heated state. A heat reservoir with a thermal capacity in the range of metals is advantageous, wherein a metallic heat reservoir is advantageous, especially at least predominantly of copper, aluminum or steel. The heat reservoir and pyro unit are advantageously disposed relative to each other and dimensioned such that the heat reservoir absorbs the major part of the pyrotechnically generated heat.

The heat storage can be further improved if two heat reservoirs are disposed on both sides of the pyro unit. A symmetrical arrangement relative to each other is advantageous. Likewise, a plate shape of the heat reservoir is advantageous that especially has a dimension in the thickness direction that is no more than 20% of the dimensions in the two directions perpendicular thereto. The heat reservoir and pyro unit can each be implemented here as a plate and can especially form a sandwich structure.

In order for a fast start of electricity generation to occur, heat from the combustion process must be rapidly transferred to the at least one thermo generator. Whereas the combustion generally proceeds very rapidly and also the generator element(s) of the thermo generator respond(s) rapidly to heat, the heat transfer through the heat reservoir can take a relatively long time until sufficient heat reaches the thermo generator. In order to reduce the heat transfer time, it is advantageous if the thickness of the heat reservoir varies in the heat propagation direction. The thinner the heat reservoir is, the faster the heat transfer proceeds from its hot side to its cold side. More heat can be stored at the thicker points, however. This enables a good compromise between fast heat transfer and good storage capacity to be achieved. The heat propagation direction here is the direction from the pyro unit to a thermo generator, especially the direction of the shortest distance.

Advantageously, the heat reservoir is e.g. a plate, especially a metal plate, provided with recesses on its side facing the pyro unit. This enables a good thickness variation of the heat reservoir to be achieved. Advantageously, the recesses reduce a heat transfer path through the heat reservoir by at least 50% relative to an average heat transfer path of a segment of the heat reservoir between the recesses. The heat reservoir in the region of the recesses is thus no more than half as thick as between the recesses in relation to a direct path from the pyro unit to a thermo generator. The recesses can be filled with fuel.

In order to achieve a rapid heat transfer from the heat reservoir to the at least one thermo generator and hence a rapid supply of power to the electrical elements of the fuse, it is proposed that the generator elements of the at least one thermo generator are disposed in zones opposite the recesses on the heat reservoir. Arranging a generator element in the region of a zone opposite a recess in the heat reservoir makes a faster heat transfer to the generator element possible. If the generator elements are Peltier elements, it is also possible to set or dispose the recesses in the heat reservoir such that they lie on the side facing the pyro unit such that the respective opposing zones are each between the p-doped semiconducting element and the n-doped semiconducting element of a Peltier element, especially centrally between them.

On the one hand it is advantageous to dimension a heat reservoir to be as small as possible in order to save space and weight in the fuse. On the other hand, the heat reservoir must be able to store sufficient energy so that electrical energy can be generated during a targeted time period. The hotter the heat reservoir is heated up to, the greater is the stored quantity of heat. An upper temperature limit is, however, determined by the generator element(s) of the thermo generator that is or are damaged above a temperature limit. With generator elements soldered using soft solder, such temperature limits are generally about 200° C. In order to achieve good heat storage, it is however proposed that the pyro unit and the heat reservoir are dimensioned such that the heat reservoir is at least briefly heated to above a melting temperature of solder, e.g. to at least 300° C. on its cold side after ignition of the pyro unit in normal operation. The generator elements can briefly withstand such a temperature, so that brief overheating of the generator element is acceptable. Solder between a generator element and an element connected to the same, e.g. an electrical connector or a different mounting structure, can melt, but this can be tolerated following launching or during the flight if the generator element is otherwise mounted, e.g. by clamping between two elements. In this respect it is advantageous with regard to the generation of as much electrical energy as possible if the pyro unit and the heat reservoir are dimensioned such that the heat reservoir is at least briefly heated up on its cold side to a temperature at which a solder joint on a generator element melts after ignition of the pyro unit in normal operation. The cold side is facing a thermo generator. The temperature or the specific value of 300° C. is to be understood to occur where the thermo generator is in direct contact with the heat reservoir, so that the heat reservoir is heated up to the temperature or to 300° C.

Generator elements, such as e.g. Peltier elements, are usually disposed between electrical connectors on both sides, each being soldered to the corresponding generator element. In the case of Peltier elements, the p-doped and n-doped semiconducting elements of a Peltier element are connected together on one side by an electrical connector and on the other side the n-doped semiconducting element is connected to the p-doped semiconducting element of the next Peltier element by an electrical connector and so on, so that current flows successively through the p-doped and n-doped semiconducting elements of the first Peltier element and then of the next Peltier element. At a temperature significantly above 200° C., the solder melts and the thermo generator breaks down. In order to keep the generator elements stable in place between the electrical connectors even in the event of brief overheating, it is proposed that they are clamped on both sides between the electrical connectors. By means of pressure on a generator element on both sides, the generator element can remain positioned in a stable manner in the event of brief melting of the joining solder. There is still a sufficient holding effect for this by means of the pressure.

During firing a projectile is subjected to an acceleration of a multiple of 10,000 g. Accelerations of up to 100,000 g are possible. Suitable shock testing of the fuse is to be provided. In order to counteract a defect of the power supply unit, it is proposed that the at least one thermo generator contains one or more generator elements that is or are embedded in a mounting structure with a holding material. The holding material can be synthetic resin or a different plastic that is electrically insulating. The mounting structure can contain two mounting plates that hold the generator elements on both sides.

When operating the power supply unit this absorbs a great deal of heat as a result of the combustion process. This also passes to the at least one cold side, so that a temperature difference may be too small and too rapid for adequate current or voltage generation to occur. In order to counteract such heating up of the cold side, it is advantageous to dispose a cold reservoir on the at least one cold side. This is advantageously made of the same material as the heat reservoir, e.g. of copper. A good heat output from the cold reservoir can be achieved if the same is especially directly disposed on a metallic outer missile wall. The cold reservoir can retain coldness for a relatively long period and the current generation process can remain maintained for a long time.

Alternatively, it is possible to directly use the outer missile wall as a cold reservoir. In this respect the cold side is then directly disposed on the outer missile wall. For this purpose it is advantageous if the outer missile wall is implemented thicker in the region of the cold side than in the surroundings.

In order to enable very fast electricity generation it is advantageous if the fuel of the pyro unit has a short burn time. A maximum of 2% of the time for which the power supply unit provides electricity for the operation of electrical elements of the fuse is advantageous.

The ignition of the pyro unit advantageously takes place mechanically, because generally there is no electrical energy available, e.g. for a glow wire. Reliable mechanical ignition can be achieved if the pyro unit contains an igniter that is provided for piercing ignition when the projectile is fired. For this purpose the igniter advantageously has an ignition charge that is ignited by a piercing element. For its part the ignition charge ignites a burner element of the pyro unit. For ignition of the ignition charge the piercing element can be accelerated by the firing acceleration on the ignition charge and ignites the charge when it impinges, e.g. by friction or impact. In order to prevent unwanted impingement of the piercing element on the ignition charge, the element is advantageously secured with a locking element or holding element. This is advantageously implemented such that it is torn off by the firing acceleration during firing, i.e. with a typical firing acceleration profile for the projectile, and so the piercing element is released for acceleration onto the ignition charge.

Rapid burning of the burner element can be achieved if the element is ignited from the center. For this purpose an ignition firing of the ignition charge is directed towards the center of the burner element. However, with such an ignition approach a relatively large construction is disadvantageous because the ignition charge has to be positioned above or below the burner element. The space can be kept small if radial ignition of the burner element takes place, i.e. radially from the outside. For this purpose the igniter is advantageously provided for radial ignition of the pyro element.

In order to achieve mechanical ignition reliably, it is also advantageous if the ignition of the pyro element takes place using axial ignition acceleration of a piercing element. Here the piercing direction can deviate from the ignition direction. A change of direction of the ignition firing can be achieved by a channel with a diversion that deflects the ignition firing from an axial direction into a radial direction. Alternatively, the ignition charge already has a radial ignition direction, even if it was ignited by an axial impact.

The invention is also aimed at a method for supplying electrical elements of a fuse of a missile with electrical energy, with which at least one hot side of a power supply unit of a power supply system is heated, at least one thermo generator of the power supply unit is generating electricity and the same is fed to the electrical elements.

In order to enable rapid and reliable electricity generation, it is proposed that according to the invention a combustion process of a pyro unit of the power supply unit is initiated for heating the at least one hot side.

The previous description of advantageous configurations of the invention contains numerous features that are sometimes reproduced as a combination of several features in the individual dependent claims. The features can, however, also be advantageously considered individually and can be combined to form other useful combinations. In particular, the features can each be combined individually and in any suitable combination with the method according to the invention and the device according to the invention in accordance with the independent claims.

The properties, features and advantages of this invention described above and the manner in which they are achieved are clearly and unambiguously understandable in connection with the following description of the exemplary embodiments, which are explained in detail in connection with the figures. The exemplary embodiments are used to explain the invention and do not limit the invention to the combination of features stated therein, nor in relation to functional features. Moreover, features of any exemplary embodiment suitable for this can also be explicitly considered in isolation, removed from an exemplary embodiment, introduced into a different exemplary embodiment as an extension thereof and/or combined with any one of the claims.

Other features which are considered as characteristic for the invention are set forth in the appended claims.

Although the invention is illustrated and described herein as embodied in a missile fuse and a method of supplying electrical energy to the missile fuse, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is an illustration of an artillery shell with a schematically illustrated fuse with a power supply system according to the invention;

FIG. 2 is a diagrammatic, side view of the power supply system;

FIG. 3 is an illustration showing an igniter next to the power supply system from FIG. 2;

FIG. 4 is an illustration of an alternative igniter; and

FIG. 5 is an illustration showing a section of another projectile.

### DETAILED DESCRIPTION OF THE INVENTION

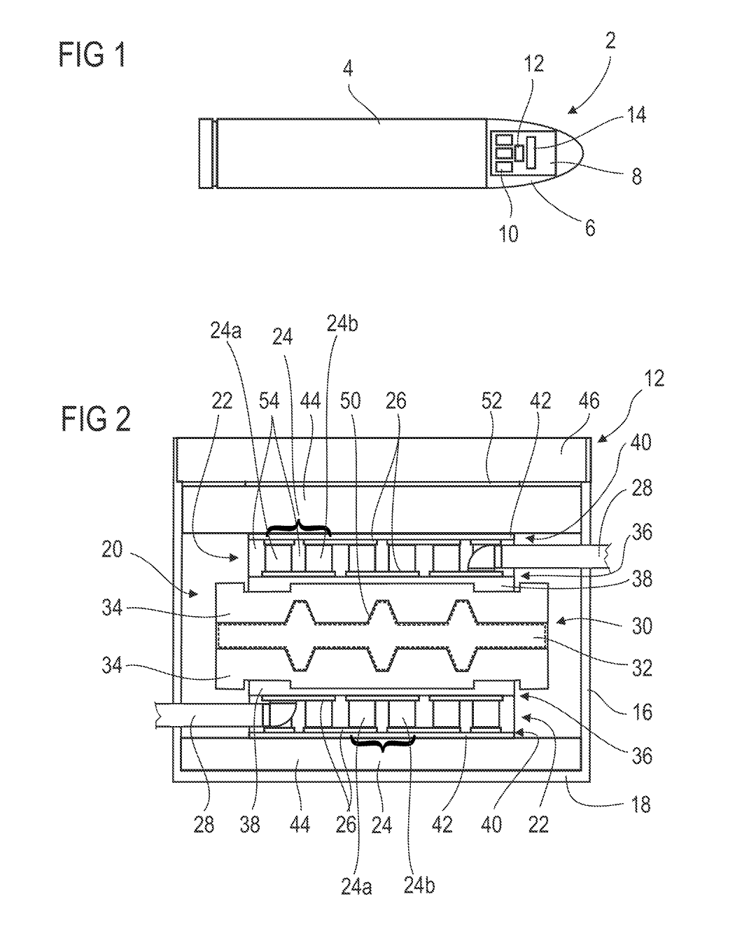

Referring now to the figures of the drawings in detail and first, particularly to FIG. 1 thereof, there is shown a missile 2 in the form of an artillery shell with a rear active charge part 4 and a front head part 6, in which a fuse 8 is disposed. The fuse 8 is only schematically illustrated in FIG. 1 and accommodates a row of electrical elements 10, which are supplied with electrical operating voltage during operation by a power supply system 12. The elements 10 are e.g. part of a seeker head of the missile 2 that is provided for target tracking and guiding the missile 2. A control unit 14 is likewise supplied with operating voltage by the power supply system 12 and controls the electrical elements 10. The elements 10 can be a proximity sensor, an infrared sensor, a time fuse, a distance measurement device and similar.

The power supply system 12 is illustrated in FIG. 2 in a side view, wherein its housing 16 is only indicated, so that only its side walls and floor 18 can be identified. The power supply system 12 contains a power supply unit 20, which has two thermo generators 22. Each of the two thermo generators 22 contains a number of generator elements 24, which are disposed in a two-dimensional grid and are connected in series by electrical connectors 26.

The generator elements 24 are formed of a semiconducting material with a p-n junction and are prepared to utilize the Seebeck effect. They generate electrical energy from a temperature difference between their hot side and their cold side, which is also maintained during the operation of the electrical elements 10, whereby an operating current for the electrical elements 10 is made available. Each generator element 24 contains a Peltier element with two e.g. square elements 24a, 24b, each of p-doped and n-doped semiconducting material such as e.g. lead telluride, bismuth telluride or another semiconducting material. The electrical connectors 26 respectively connect the p-doped element 24a of a generator element 24 to the n-doped element 24b of a generator element 24 or vice-versa. By connecting the generator elements 24 in series using the electrical connectors 26, each of the two thermo generators 22 produces contributions to the operating voltage of the electrical elements 10 of the fuse 8. The thermo generators 22 can be connected in series, so that each of the two thermo generators 22 e.g. only generates part of the operating voltage of the electrical elements 10, e.g. respectively between 50% and 60%, or in parallel, so that each of the two thermo generators only produces part of the operating current for the electrical element. The operating voltage is transferred to the electrical elements 10 by electrical tappings 28.

A pyro unit 30 with a burner element 32 is disposed between the two thermo generators 22 of the power supply unit 20. The burner element 32 is enclosed on both sides by two heat reservoirs 34, which are respectively disposed between the burner element 32 and one of the thermo generators 22. The burner element 32 contains a solid state combustion body disposed in a housing, the body being burned after ignition and hereby a large amount of energy is released as heat. The heat is transferred via the two heat reservoirs 34 to the hot side 36 of the power supply unit 20; more accurately speaking to the respective hot side 36 of the two thermo generators 22. The hot side 36 is essentially filled by a mounting plate 38, which extracts heat from the corresponding heat reservoir 34 and transfers it via the electrical connectors 26 or directly to the generator elements 24. A mounting plate 42 is likewise disposed on a cold side 40 of the thermo generators 22, being implemented to be electrically insulating and thermally conducting like the mounting plate 38. A cold reservoir 44 is respectively thermally connected to the cold side 40, wherein the lower cold reservoir 44 in FIG. 2 is thermally connected to the floor 18 of the housing 16 and the upper cold reservoir 44 in FIG. 2 is thermally connected to an outer missile wall 46, so that the cold reservoir 44 transfers the heat transferred to it to the floor 18 or to the fuse wall 46.

With the exemplary embodiment from FIG. 2 the generator elements 24 are electrically connected to each other by the electrical connectors 26, e.g. by soldering with a soft solder. Instead of separate electrical connectors 26, it is also conceivable and advantageous that the mounting plates 38, 42 themselves are fitted with electrical connectors, e.g. in the form of conducting tracks that are incorporated in the mounting plates 38, 42. The generator elements 24 can be directly connected to the mounting plates 38, 42, e.g. soldered. Alternatively, it is possible that the mounting plates 38, 42 have soldering areas, e.g. a metal layer extending over regions of the mounting plates 38, 42, and the electrical connectors 26 are soldered to the soldering areas. The soldering areas can be conducting tracks.

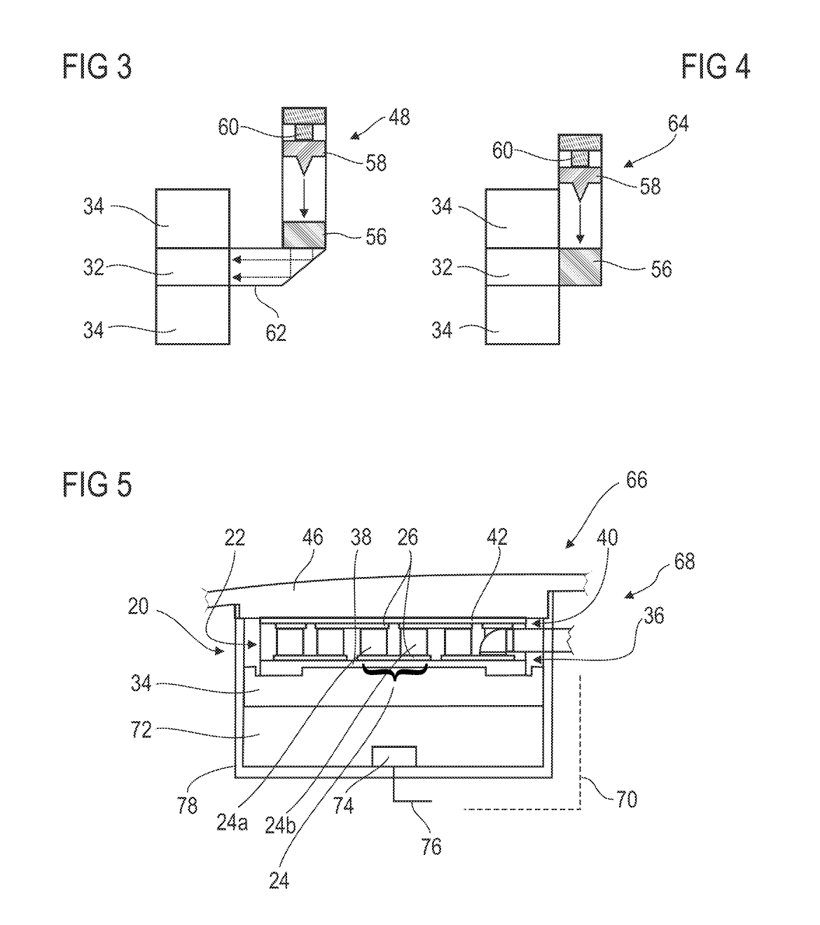

When launching the missile 2 from a tube, an igniter 48 (FIG. 3) is activated and ignites the burner element 32 of the pyro unit 30. Within a few milliseconds the entire solid fuel of the burner element 32 burns and releases heat. The heat penetrates into the heat reservoir 34 at the hot side of the heat reservoir 34 and passes through the heat reservoir 34 to its cold side, which is in contact with the hot side 36 of the corresponding thermo generator 22. The mounting plate 38 and the hot side electrical connector 26 heat up so that a temperature drop exists across the generator elements 24. The generator elements 24 generate a voltage from the temperature drop, the voltage increasing with increasing temperature difference. Where the temperature difference is large enough there is an operating voltage for the elements 10, so that the elements can be operated over a time period of about 90 s.

The burner element 32 is implemented as a generally planar plate with a round cross-section, so that the heat produced by the burner element 32 is transferred to both heat reservoirs 34 over a large area with generally equal cross-sections. The heat produced is substantially taken up by the two heat reservoirs 34, wherein the reservoirs heat up and then slowly cool down again as a result of the discharge of energy into the generator elements 24. In order to achieve high thermal storage capacity and also a rapid heat transfer from the hot side to the cold side of the heat reservoir 34, the reservoirs are made of copper.

Despite its small thickness of e.g. 1 mm, the heat still needs a certain time to pass to a sufficient extent to the cold side of the heat reservoir 34 so that the temperature difference at the generator elements 24 necessary for the operating voltage can be produced. The heating up period to operating temperature lasts e.g. a few 100 ms. In order to reduce the heating up time of the cold side of the heat reservoir 34, both heat reservoirs 34 contain recesses 50 on their hot sides in the form of indentations that can be filled with solid fuel of the burner element 32, as is indicated by the dashed line in FIG. 2, which indicates the outline of the solid fuel. At the lowest point of the recesses 50, the distance to the cold side of the corresponding heat reservoir 34 is less than half the distance between the hot side and the cold side between the recesses 50. As a result, the cold side of the relevant heat reservoir in the regions opposite the recesses 50 heats up significantly faster, so that the operating temperature—i.e. the temperature that is necessary to provide the operating voltage—is achieved considerably faster there. In order to distribute the heat of the hot regions to the generator elements 24 as uniformly as possible, the hot regions are disposed below the electrical connectors 26, especially symmetrically there-under, i.e. symmetrically between p-doped 24a and n-doped 24b elements of a generator element 24. The recesses 50 are thereby made relatively small relative to the total volume of the corresponding heat reservoir 34 and the heat reservoir 34 still retains a high thermal storage capacity.

The burner element 32 and the heat reservoir 34 are implemented and dimensioned relative to each other such that the peak temperature on the cold side of the heat reservoir 34 and the electrical connector 26 exceeds 300° C. The temperature is critical for the generator elements 24, which are connected by a metallic soft solder to the electrical connectors 26. The solder melts at such high temperatures that the solid connection of the generator elements 24 to their electrical connectors 26 is loosened.

In order to avoid degradation of the thermo generators 22, the same are clamped between the heat reservoir 34 and the cold reservoir 44, or between the mounting plates 38, 42, i.e. are held under pressure. In this way the generator elements 24 still remain in position with sufficient residual stability, so that electricity generation is maintained for a sufficiently long period even for the greatest heat. Moreover, the generator elements 24 form a sufficiently strong bond with the mounting plates 38, 42. The pressure can be exerted on the thermo generators 22 by a pressure element 52, which is a plate spring in the exemplary embodiment shown in FIG. 2. However, other pressure elements are also conceivable. Alternatively, the power supply unit 20 together with the cold reservoirs 44 can be held under pressure in the housing 16, which can be achieved e.g. by flanging the side walls of the housing 16 under tension by the cover.

During launching of the missile 2, high acceleration forces act on the missile 2 and also on the power supply system 12, so that the power supply system is loaded with several 10,000 g, especially up to 100,000 g. In order to prevent destruction of the thermo generators 22, especially of the generator elements 24, the generators are embedded using a holding material 54, e.g. a synthetic resin, with a mounting structure, which in the exemplary embodiment contains the mounting plates 38, 42. The mounting structure and the generator elements 24 with the electrical connectors 26 thus form a solid monolithic block, which is clamped between the heat reservoir 34 and the cold reservoir 44.

An igniter 48 for igniting the burner element 32 is shown in FIG. 3. The igniter 48 is part of the pyro unit 30 and contains an ignition charge 56 of a solid fuel, which can easily be ignited by penetration by a piercing element 58. When launching the missile 2 the same is accelerated forwards, so that the inertia of its components causes a force in the direction of the vertical arrow of FIG. 3 that is opposite to the acceleration direction. The piercing element 58 tears a mounting element 60 during the launching acceleration as a result of its inertia, the mounting element 60 holding the piercing element 58 fixedly in place in all other situations. The piercing element 58 is accelerated by its inertia in the direction of the arrow towards the ignition charge 56 and drills its tip into the ignition charge 56, so that the charge is ignited. The hot combustion gases are guided by a flame duct 62 to the burner element 32, which is thereby ignited laterally. The burner element now burns through completely. The flames of the ignition charge 56 oriented in the axial direction are diverted by the flame duct 62 and reach the burner element 32 in the radial direction. The arrangement has the advantage that the plane of the extent of the burner element 32 and of the heat reservoir 34 can be oriented perpendicularly to the launch direction of acceleration of the missile 2 and thereby undergoes an acceptable and homogeneous load during launch. By arranging the igniter 48 laterally from the burner element 32, the axial structural height of the power supply system 12 can be kept small, so that its space requirement is advantageous despite the known required flight path of the piercing element 58 to the ignition charge 56.

An alternative form of an igniter 64 is illustrated in FIG. 4. In contrast to the exemplary embodiment of FIG. 3, the flame duct 62 and the diversion of the flames from the ignition charge 56 are dispensed with. The ignition charge 56 is disposed immediately adjacent to the burner element 32 and ignites the same directly.

FIG. 5 shows a section of another missile 66 in the form of a projectile whose power supply system 68 is part of a fuse 70 that is only indicated. The following description is limited essentially to the differences from the exemplary embodiment in FIGS. 1 and 2, reference being made to the features and functions that remain the same. Essentially unchanged components are in principle designated by the same reference characters and features that are not mentioned are assumed to be in the following exemplary embodiment without being described again.

The power supply system 68 contains only a single thermo generator 22, which is disposed directly on the wall of the fuse, which as already shown in FIG. 2 forms part of the wall of the projectile or outer missile wall 46, so that ambient air flows directly past the wall of the projectile 66 during the flight of the projectile and cools the wall. The outer missile wall 46 acts as a cold reservoir for the power supply system 68 and is for this purpose thicker in the region of the power supply system 68 than in the surroundings thereof. Moreover, this has the advantage of easier attachment than with uniform wall thickness. Alternatively, the wall 46 can be implemented with uniform thickness and an additional element directly joined to the wall 46 and in contact with the wall 46 over the entire surface of the thermo generator 22 transfers the heat from the thermo generator 22 to the outer missile wall 46.

An igniter 74 that is embedded in a pyro unit 72 is ignited via a signal line 76. Alternatively, an igniter 48, 64 as already described can be used. A housing 78 of the power supply system 68 closes the same externally and insulates it in such a way that heat of the pyro unit 72 only penetrates through the housing 78 in an amount that is operationally permitted. Electrical elements 10 of the wall of the projectile, e.g. of a seeker head, are not disrupted during operation in this case.

For electricity generation the burner element of the pyro unit 72 is ignited and outputs heat to the heat reservoir 34, which largely passes the heat on to the thermo generator 22 with the generator elements 24 connected in series. The further process is described for the preceding exemplary embodiment.

The exemplary embodiments shown in FIGS. 2 and 5 are so similar that elements of each exemplary embodiment can readily be assumed to be in the other exemplary embodiment without departing from the scope of the invention. An example of this can be the thickening of the outer missile wall 46 in the region of the power supply system 68, which is of course also possible with the power supply system 12.

The following is a summary list of reference numerals and the corresponding structure used in the above description of the invention:
2 missile
4 active charge part
6 head part
8 fuse
10 element
12 power supply system
14 control unit
16 housing
18 floor
20 power supply unit
22 thermo generator
24 generator element
24a p-doped element
24b n-doped element
26 electrical connector
28 electrical tapping
30 pyro unit
32 burner element
34 heat reservoir
36 hot side
38 mounting plate
40 cold side
42 mounting plate
44 cold reservoir
46 outer missile wall
48 igniter
50 recess
52 pressure element
54 holding material
56 ignition charge
58 piercing element
60 mounting element
62 flame duct
64 igniter
66 missile
68 power supply system
70 fuse
72 pyro unit
74 igniter
76 signal line
78 housing

1. A fuse of a missile, the fuse comprising:
a power supply system having a power supply unit with at least one hot side, at least one cold side and at least one thermo generator disposed between said hot and cold sides, said power supply unit having a pyro unit on said at least one hot side for producing heat by a combustion process.

2. The fuse according to claim 1, wherein said at least one thermo generator is one of two thermo generators, said pyro unit is disposed between said two thermo generators.

3. The fuse according to claim 1, wherein said pyro unit contains a burner element being a planar plate.

4. The fuse according to claim 1, wherein said power supply system has a heat reservoir disposed between said at least one thermo generator and said pyro unit.

5. The fuse according to claim 4, wherein said heat reservoir has a thickness varying in a direction of heat propagation.

6. The fuse according to claim 4, wherein said heat reservoir has recesses formed therein on a side facing said pyro unit.

7. The fuse according to claim 6, wherein said thermo generator has generator elements, said generator elements are disposed in zones opposite said recesses on said heat reservoir.

8. The fuse according to claim 7, wherein:
said generator elements have a solder joint;
said heat reservoir has a cold side; and
said pyro unit and said heat reservoir are dimensioned so that after igniting said pyro unit in normal operation said heat reservoir is at least briefly heated up on said cold side to a temperature at which said solder joint on said generator elements of said at least one thermo generator melts.

9. The fuse according to claim 1, wherein:
said power supply system has a mounting structure with a holding material; and
said at least one thermo generator contains at least one generator element embedded in said mounting structure with said holding material.

10. The fuse according to claim 1, wherein said at least one cold side is disposed directly on an outer missile wall.

11. The fuse according to claim 1, wherein:
said power supply system has a cold reservoir; and
said at least one thermo generator has a cold side disposed on said cold reservoir and said cold reservoir is disposed on an outer missile wall.

12. The fuse according to claim 1,
further comprising electrical components; and
wherein said pyro unit has a fuel whose burn time is a maximum of 2% of a time for which said power supply unit provides electricity for an operation of said electrical components.

13. The fuse according to claim 1, wherein said pyro unit contains an igniter that is provided for piercing ignition during launching of the missile.

14. The fuse according to claim 13, wherein said pyro unit contains a piercing element, said igniter is provided for radial ignition of said pyro unit using an axial ignition acceleration of said piercing element.

15. A method for supplying electrical elements of a fuse of a missile with electrical energy, which comprises the steps of:
initiating a combustion process of a pyro unit of a power supply unit for heating a hot side, the heating of the hot side of the power supply unit of a power supply system resulting in at least one thermo generator of the power supply unit producing electricity; and
feeding the electricity to the electrical elements.
